(19) United States
(12) Patent Application Publication
(10) Pub. No.: US 2022/0360279 A1
(43) Pub. Date: Nov. 10, 2022

(54) DATA COMPRESSION TECHNOLOGIES

(71) Applicant: Intel Corporation, Santa Clara, CA (US)

(72) Inventors: Xiaoyan BO, Shanghai (CN); Junyuan WANG, Shanghai (CN); Xinghong CHEN, Shanghai (CN); Chengfei ZHU, Shanghai (CN); Shuai YUAN, Shanghai (CN); Weigang LI, Shanghai (CN); Dongsheng LIANG, Shanghai (CN); Fei YU, Shanghai (CN)

(21) Appl. No.: 17/870,427

(22) Filed: Jul. 21, 2022

(30) Foreign Application Priority Data
Jul. 1, 2022 (CN) PCT/CN2022/103243

(51) Int. Cl. H03M 7/30; H03M 7/46

(52) U.S. Cl. CPC H03M 7/3088; H03M 7/6023; H03M 7/46

(57) ABSTRACT

Examples described herein relate to performing data compression by performing dictionary matching of data using hardware circuitry to generate dictionary matched results and post-processing of dictionary matched results using software executed by a processor. In some examples, dictionary matching includes LZ77 dictionary matching. In some examples, dictionary matching occurs on multiple segments of data in parallel.

### RELATED APPLICATION

This application claims the benefit of priority to Patent Cooperation Treaty (PCT) Application No. PCT/CN2022/103243, filed Jul. 1, 2022. The entire content of that application is incorporated by reference.

### BACKGROUND

Vast amounts of data are stored and transmitted in data centers and through the Internet. Data Compression (DC) can reduce data storage space, data transmission time, and communication bandwidth. However, DC can involve computing intensive operations and may performance delays due to applied algorithm and constraints on available computing resources. DC algorithms can improve performance, provide higher compression ratio, and provide faster compression and decompression. Example compression algorithms include Facebook® Zstandard (or Zstd) and Google® Broth. Currently, the Zstd specification has published 9 versions and each version varies in algorithm implementation. Accordingly, improving speed of operation of compression based on Zstd specification using hardware offload engines can be challenging due to the evolving nature of the Zstd specification.

### BRIEF DESCRIPTION OF THE DRAWINGS

FIG. 1 depicts an example of data compression operations.

FIG. 2 depicts an example of dictionary encoding and post processing.

FIG. 3 depicts an example of operations to offload data to an accelerator to perform LZ77 dictionary matching.

FIG. 4 depicts an example of parallel acceleration of dictionary encoding.

FIG. 5 depicts an example of QATZIP API flow for an application to submit a data compression request to a QAT accelerator.

FIG. 6 depicts an example of ZSTD API flow for an application to submit a data compression request to an accelerator.

FIG. 7 depicts an example of post processing.

FIG. 8 depicts a structure of LZ4s frame format.

FIG. 9 depicts an example of conversion of LZ77 based on LZ4s to ZSTD sequence.

FIG. 10 depicts an example process.

FIG. 11 depicts an example computing system.

FIG. 12 depicts an example system.

### DETAILED DESCRIPTION

At least to attempt to reduce power use and improve speed of performance of data compression (DC), a system can offload a computing portion of DC to an accelerator and perform post-processing of compressed data using a processor-executed software. Use of a segmented implementation can accommodate advanced DC algorithms with varying post-processing operations. For example, the system can perform DC based on Zstd and based on Google® Broth as well.

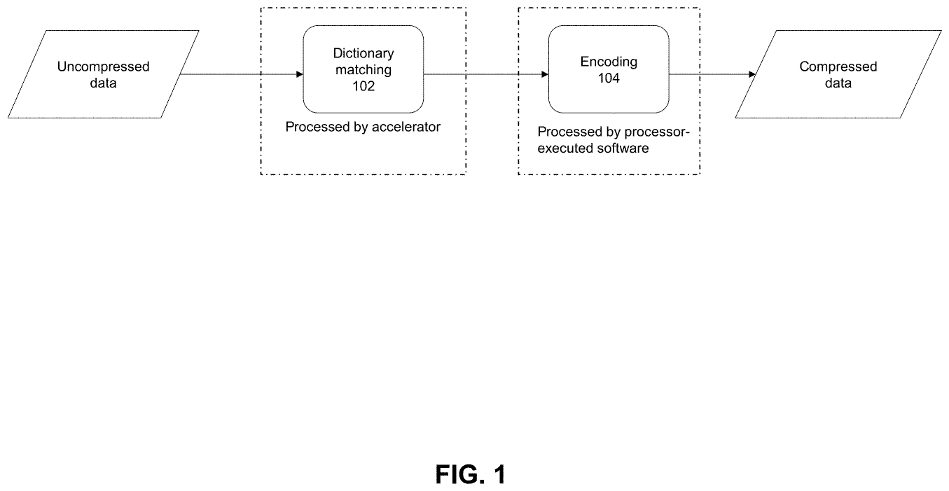

FIG. 1 depicts an example of data compression operations. Data compression can include operations of dictionary matching 102 and encoding 104. Data compression can perform lossless or lossy data compression. Lossless encoding schemes can include encoding schemes such as the Lempel-Ziv (LZ) family including, but not limited to, LZ77, LZ78, LZX, LZ4, LZS, Zstandard, DEFLATE, Huffman coding, GNU zip (gzip), GIF (Graphics Exchange Format), Google® Broth, Snappy standards and derivatives, and others. For example, LZ77 streams are described in Ziv et al., “A Universal Algorithm for Sequential Data Compression” IEEE Transactions on Information Theory (May 1977). Lossy data compression algorithms can include coding formats from Joint Photographic Experts Group (JPEG) as well as discrete cosine transform, Fractal compression, Wavelet scalar quantization, or others. Data compression can be performed to at least of text, files, images, videos, or other data or executable instructions.

Dictionary matching 102 can process data (e.g., uncompressed or compressed data) to generate encoded data. An accelerator (e.g., application specific integrated circuits (ASICs), field programmable gate arrays (FPGAs)) or other circuitry can perform dictionary matching of segments of data in parallel. For example, an accelerator can include Intel® QuickAssist Technology (QAT).

Dictionary matching 102 can apply a dictionary coder that operates by searching for a match between text in the message to be compressed and a set of strings in a dictionary. Dictionary matching 102 can use prior input data information of the input data stream that can be referred to as history. LZ lossless data compression can dynamically build a dictionary while uncompressed data is received, and compressed data is transmitted. LZ lossless data compression can search the history for a string that matches a portion of the input data stream. When a match for a string is found, dictionary matching 102 can encode the matched portion of the input data using a reference (offset and length) to the matching string in the history. Otherwise, dictionary matching 102 can encode a next character of the input data stream as a raw data code or a “literal” that designates the character as plain text or clear text. The stored clear text data can be referred to as a dictionary. A dictionary can be created during compression and re-created during decompression.

For example, for the following data, “knock. who's there? boo. boo who? boo bear,” an output from dictionary matching 102 can be: “knock [5,6]. who's there? boo. [3,5] [3,22]? [4,9][4,4]bear.”

Encoding of output from dictionary matching 102 can vary among data compression algorithms and can be implemented using a software library. Encoding 104 can encode output of dictionary matching 102 as compressed data. Examples of encoding include Huffman coding, run length coding, arithmetic coding, asymmetric numeral systems coding, and others.

While examples described herein refer to data compression, examples can be applied to perform data encryption, data decryption, data decompression, or other algorithms.

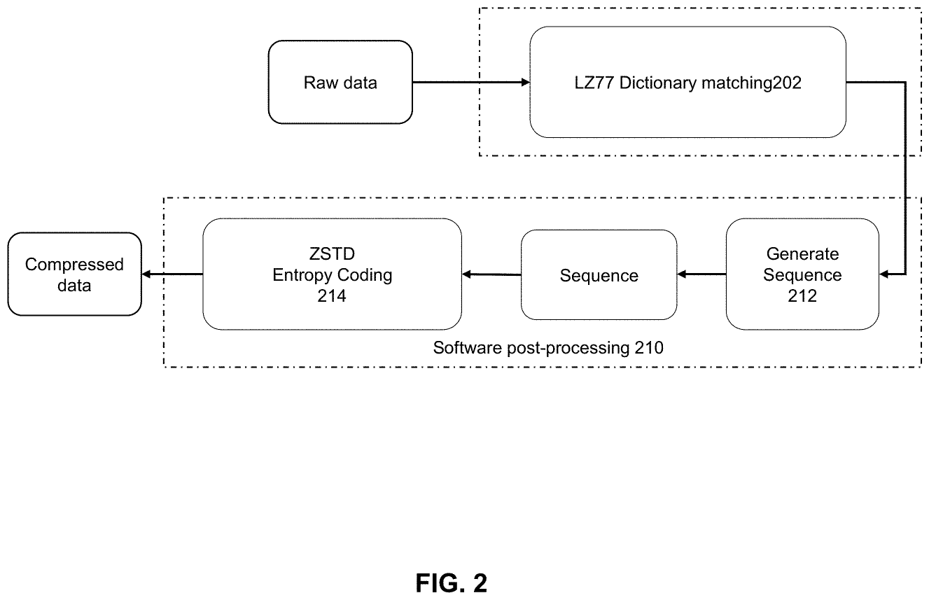

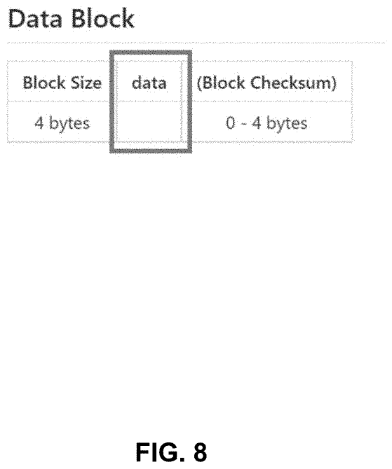

FIG. 2 depicts an example of dictionary encoding and post processing. For LZ77 dictionary matching 202, hardware can utilize QAT Zstd, FPGA, ASIC, or other circuitry. QAT includes compression slices or circuitry to perform dictionary matching to generate LZ77 from input data (e.g., raw data). A compression slice can be configured to generate the LZ4s block format, which can then be used for post-processing to generate other compressed data formats. LZ4s block format can be a variant of LZ4 block format. An example LZ4s compressed block data format is described at least with respect to FIG. 8. LZ4 compressed block data format is described at least in http://github.com/lz4/lz4/blob/dev/doc/lz4_Block_format.md. LZ4s block data format is described at least in https://github.com/microsoft/lz4s

Software post-processing 210 can post process LZ77 output from LZ77 dictionary matching 202 to generate a sequence 212 and perform Zstandard (ZSTD) entropy coding 214. Other types of software post-processing can be performed such as run length coding, arithmetic, asymmetric numeral systems, Golomb, and so forth. An output from software post-processing 210 can include compressed data that can be transmitted to a receiver or stored for later access.

In some examples, dictionary encoding and/or post processing can be performed in a discrete device, a device integrated into a processor (e.g., central processing unit (CPU), graphics processing unit (GPU), accelerator, or others), part of a system on chip (SoC) with a processor (e.g., CPU, GPU, accelerator), part of a multi-chip module connected via an interposer or Embedded Multi-Die Interconnect Bridge (EMIB).

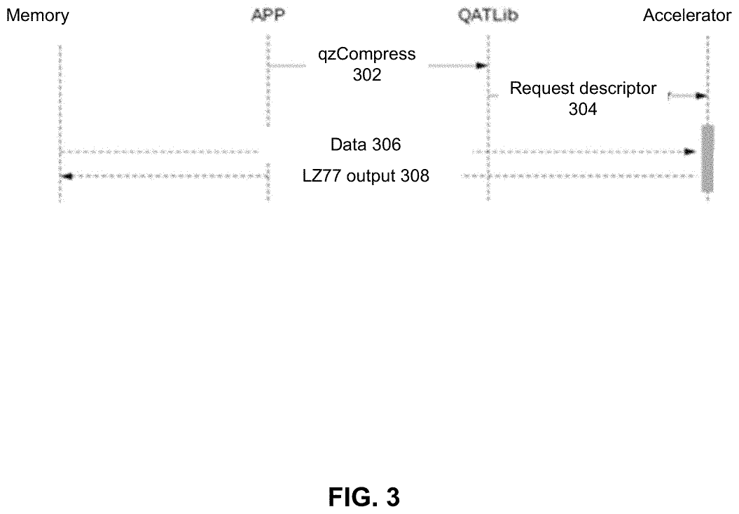

FIG. 3 depicts an example of operations to offload data to an accelerator to perform LZ77 dictionary matching. An application (APP) can issue an API of qzCompress 302 to QAT library (QATLib) to request dictionary matching in data. At 304, QATLib can issue a request descriptor 304 to an accelerator to request dictionary matching of data. Accelerator can access data 306 and perform dictionary matching on segments of data 306 in parallel. Accelerator can output LZ77 output 308 based on performance of dictionary matching.

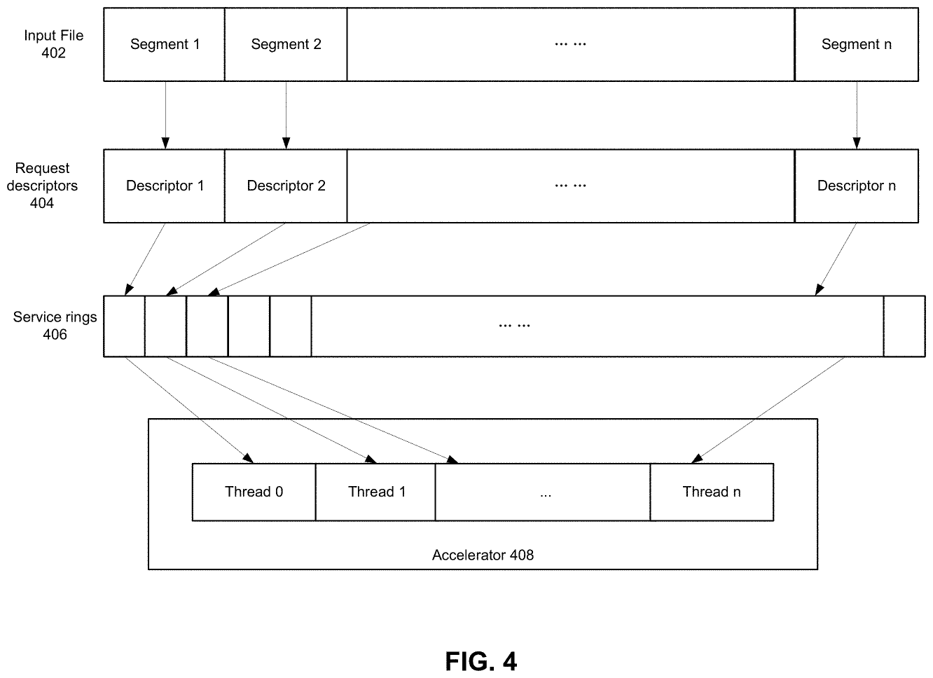

FIG. 4 depicts an example of parallel acceleration of dictionary encoding. For example, an input data file 402 can include data to be compressed. Requester descriptors 404 can be provided to request data compression of segments of input file 402. Input data file 402 can be split into multiple segments and segments can be processed in parallel by accelerator 408. Service rings 406 can enqueue data compression (DC) requests of multiple descriptors 404 corresponding service rings 406. A descriptor that requests DC by accelerator 408 can include: source data address, DC algorithm to apply (e.g., LZ77, LZ4, Deflate, or others), and destination address. A service request issued to accelerator 408 can cause multiple segments of a service request/response ring-pair (RP) 406 to be processed in parallel by multiple threads of accelerator 408.

An arbiter for accelerator circuitry 408 can poll service rings 406 for DC requests and dispatch requests with data to one or more threads running on accelerator circuitry 408 to compress segments in parallel. Where accelerator 408 is a QAT, arbiter thread can fetch data and provide data to QAT DC slice in parallel for compression. DC slices that perform data compression can perform dictionary matching. Threads that perform data compression can perform dictionary matching. Dictionary matching can include searching for a match between characters in the input file to be compressed and a set of strings in a dictionary. When the thread finds a match for a string in the input file, it substitutes the string with a reference to the string's position in the dictionary. Accelerator 408 can output an LZ77 encoded data. Threads can perform data transmission in parallel.

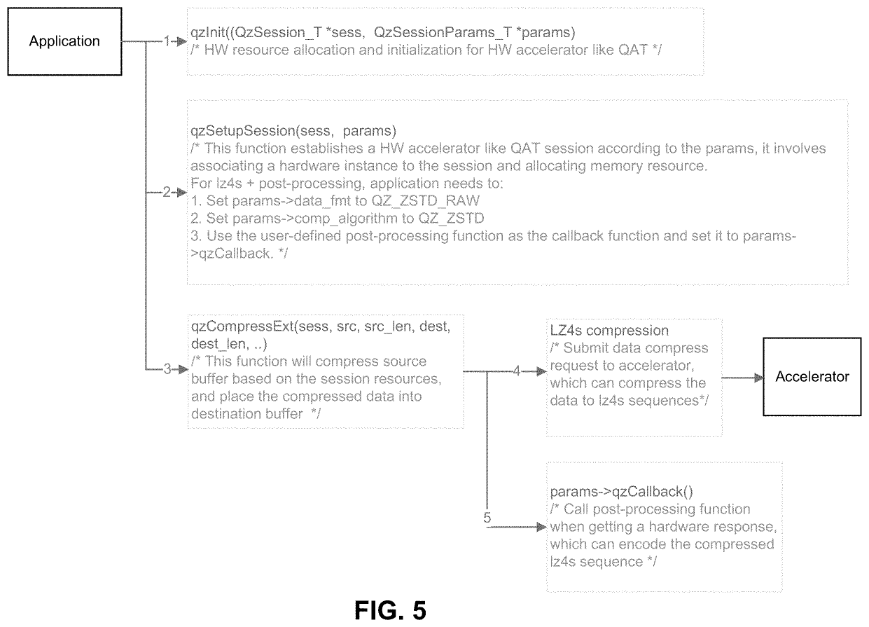

FIG. 5 depicts an example of QATZIP API flow for an application to submit a data compression request to a QAT accelerator. The application can issue APIs (1)-(3) below to an accelerator or middle software layer. APIs (1)-(3) are described for example https://github.com/intel/QATzip/blob/master/docs/QATzip-man.pdf. Implementations of APIs (1)-(3) can be hooked by QAT Software Library DC APIs which are described for example in Intel® QuickAssist Technology API Programmer's Guide (2020).

(1) QATZIP_API int qzInit(QzSession_T*sess, unsigned char sw_backup);
(2) QATZIP_API int qzSetupSession(QzSession_T*sess, QzSessionParams_T*params);
(3) QATZIP_API int qzCompressCrcExt(QzSession_T*sess, const unsigned char *src,
unsigned int *src_len, unsigned char *dest,
unsigned int *dest_len, unsigned int last,
unsigned long *crc, uint64_t *ext_rc);

In some examples, API (3) can be implemented as API calls to (4) perform LZ4s compression and (5) encode LZ4s sequence. For example, call (4) can submit data compression request to an accelerator, which can compress the data into LZ4S sequences. For example, call (5) can call a post-processing operation to encode the compressed LZ4S sequence.

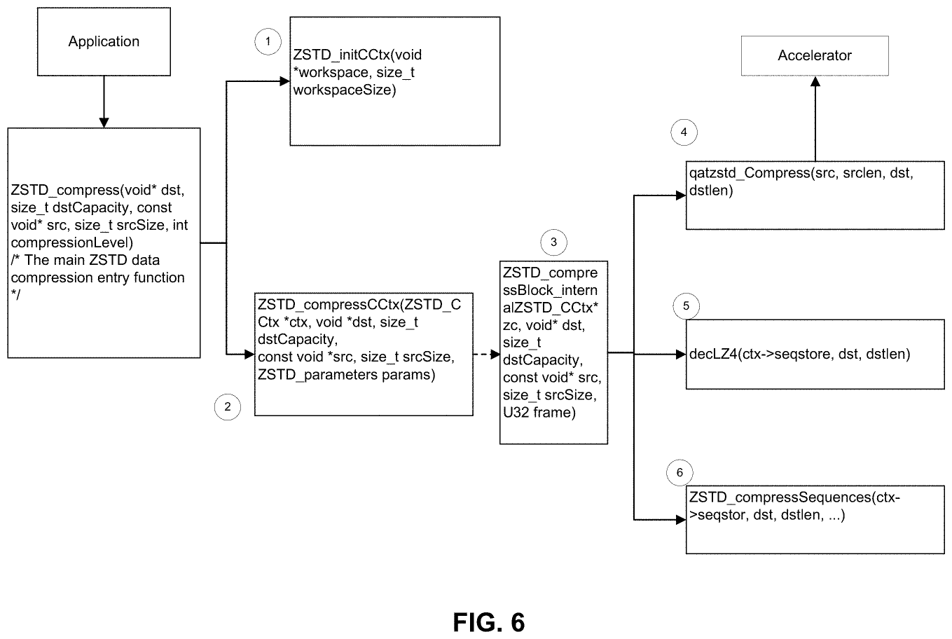

FIG. 6 depicts an example of ZSTD API flow for an application to submit a data compression request to an accelerator. The application can issue a ZSTD_compress API to accelerator or middle software layer. ZSTD_compress API can be broken down to functions (1)-(6). Functions (1) to (3) are available at least from https://github.com/facebook/zstd/blob/dev/lib/compress/zstd_compress.c

(1) ZSTD_initCCtx(void *workspace, size_t workspaceSize)
(2) ZSTD_compressCCtx(ZSTD_CCtx *ctx, void *dst, size_t dstCapacity, const void *src, size_t srcSize, ZSTD_parameters params)
(3) ZSTD_compressBlock_internal(ZSTD_CCtx* zc, void* dst, size_t dstCapacity, const void* src, size_t srcSize, U32 frame)
(4) qatzstd_Compress(src, srclen, dst, dstlen)
(5) decLZ4(ctx->seqstore, dst, dstlen)
(6) ZSTD_compressSequences(ctx->seqstor, dst, dstlen, . . . )

Function (1) can initialize a ZSTD compression context, allocate resource for accelerator, and initialize accelerator. Function (2) can use an explicit ZSTD_CCtx with hardware accelerator information, such as QAT DC service instance and QAT DC session, to compress content of a source buffer into destination buffer. Function (3) can request to compress data into one or more blocks. Function (3) can represent an internal function of Function (2) and can invoke QAT SW Library DC APIs to compress the data in source buffer and write results into destination buffer following application of ZSTD algorithms. Functions (4)-(6) can be called by Function (2) or Function (3). Function (4) can submit a data compression request to an accelerator, which can compress the data into LZ4s sequences. Function (5) can decode the compressed data into a destination buffer and store the sequence information into structure ctx->seqStore. Function (6) can call a post processing function to encode the content of ctx->seqStore into zstd format.

Post-processing can be performed on LZ77 output format (LZ4s) dictionary matched data. LZ4s is a variant of LZ4 block format, defined as an intermediate compressed block format. Post-processing can include entropy coding. However, different DC algorithms have specific post-processing requirements and implementation. For example, Zstd uses Finite State Entropy (FSE) post-processing, which is defined in RFC 8878 (2021). Other examples include run length coding or Broth, which uses Huffman coding and second order context modelling. To accommodate varying post processing operations, software-executed processes can be performed on generated dictionary matched data from the accelerator.

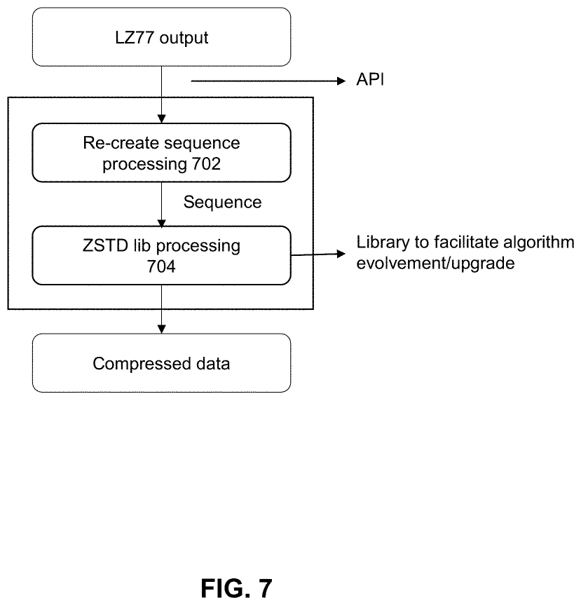

FIG. 7 depicts an example of post processing. Post processing can be called by an API to receive an LZ77 input and re-create a sequence processing to change LZ77 output format based on LZ4s to generate a ZSTD sequence (702). ZSTD lib processing 704 can perform Finite State Entropy (FSE), in some examples.

FIG. 8 depicts a structure of an LZ4s frame format. The LZ4s frame format is described at least in https://lz4.github.io/lz4/ or https://github.com/lz4/lz4/blob/dev/doc/lz4_Block_format.md

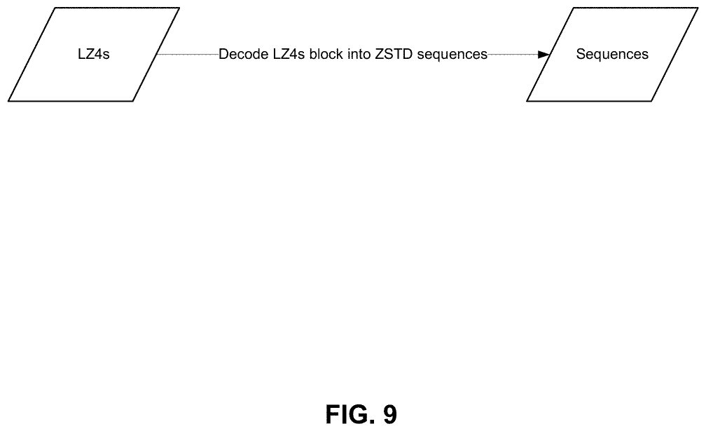

FIG. 9 depicts an example of conversion of LZ77 based on LZ4s to at least one ZSTD sequence. The following pseudocode can be used to convert LZ77 compressed data based on LZ4s into a ZSTD sequence.

```
typedef struct seqDef_s {
  U32 offset;
  U16 litLength
  U16 matchLength
} seqDef
typedef struct {
  seqDef* sequencesStart
  seqDef* sequences
  BYTE* litStart;
  BYTE* lit;
  BYTE* llCode;
  BYTE* mlCode;
```

A compressed data block can be composed of sequences. A sequence can include a suite of literals (not-compressed bytes), followed by a match copy. A sequence can start with a token. The token can be a one-byte value, separated into two 4-bits fields. The first field can use the 4 high-bits of the token and provide the length of literals to follow. The offset can represent the position of the match to be copied from. To extract the matchlength, a second token field of the low 4-bits can be accessed.

The following API and pseudocode can be used to decode LZ4s data block into a ZSTD sequence.

```
void decLz4Block(unsigned char *lz4s, int lz4sSize, ZSTD_Sequence
*zstdSeqs, unsigned int *seq_offset)
{
  unsigned char *ip = lz4s;
  unsigned char *endip = Iz4s + lz4sSize;
  while (ip < endip && lz4sSize > 0) {
      size_t length = 0;
      size_t offset = 0;
      unsigned int literalLen = 0, matchlen = 0;
      literalLen = get literal length
      ip += literal length;
      if (ip == endip) {
        // Meet the end of the LZ4 sequence
        /* update ZSTD_Sequence */
        zstdSeqs[*seq_offset].litLength += literalLen;
        continue;
      }
      offset = get matchPos
      ip += 2;
    length = get match length
    if (length != 0) {
        length += LZ4MINMATCH;
        matchlen = (unsigned short)length;
        /* update ZSTD_Sequence */
        zstdSeqs[*seq_offset].offset = offset;
        zstdSeqs[*seq_offset].litLength += literalLen;
        zstdSeqs[*seq_offset].matchLength = matchlen;
        ++(*seq_offset);
    } else {
        if (literalLen > 0) {
          /* When match length is 0, the literalLen needs to be
          temporarily stored and processed together with the
          next data block. If also ip == endip, need
          to convert sequences to seqStore.*/
          zstdSeqs[*seq_offset].litLength += literalLen;
      }
    }
  }
}
```

In a QAT-based Zstd solution, an LZ77 response callback function can be used to build a unified software stack to perform the LZ4s to sequence conversion.

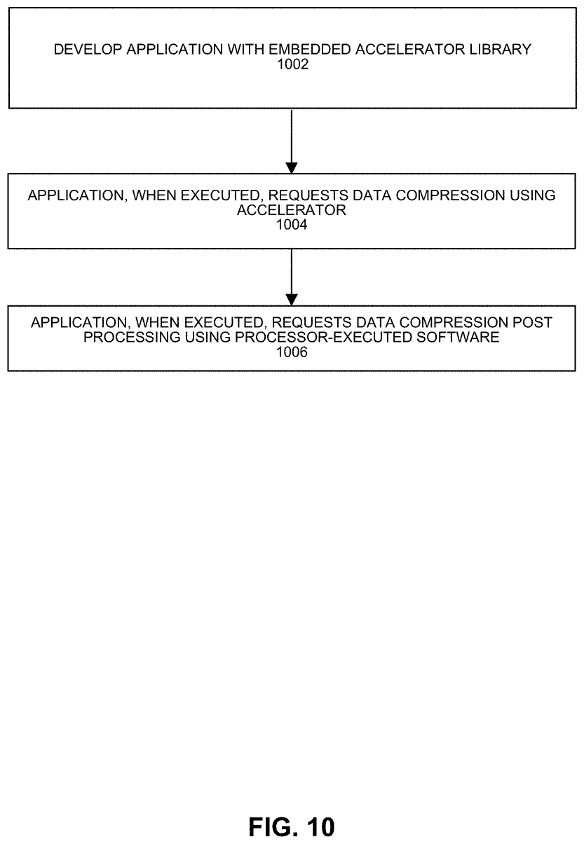

FIG. 10 depicts an example process. At 1002, a developer can develop an application (e.g., microservice, virtual machine (VM), container, or other software) to include an accelerator library. The application can perform lossless compression, encryption, decompression, decryption, or other operations such as database operations.

At 1004, the application executing on a processor can requests data compression using an accelerator based on the embedded accelerator library. The request can be provided to the accelerator to perform dictionary matching to generate LZ77 compressed data based on LZ4s.

At 1006, the application can issue a request to post-process LZ77 compressed data based on LZ4s. Post processing can be performed by software executed by a processor. Post processing can include entropy encoding, Huffman encoding, conversion of LZ77 compressed data based on LZ4s to a sequence.

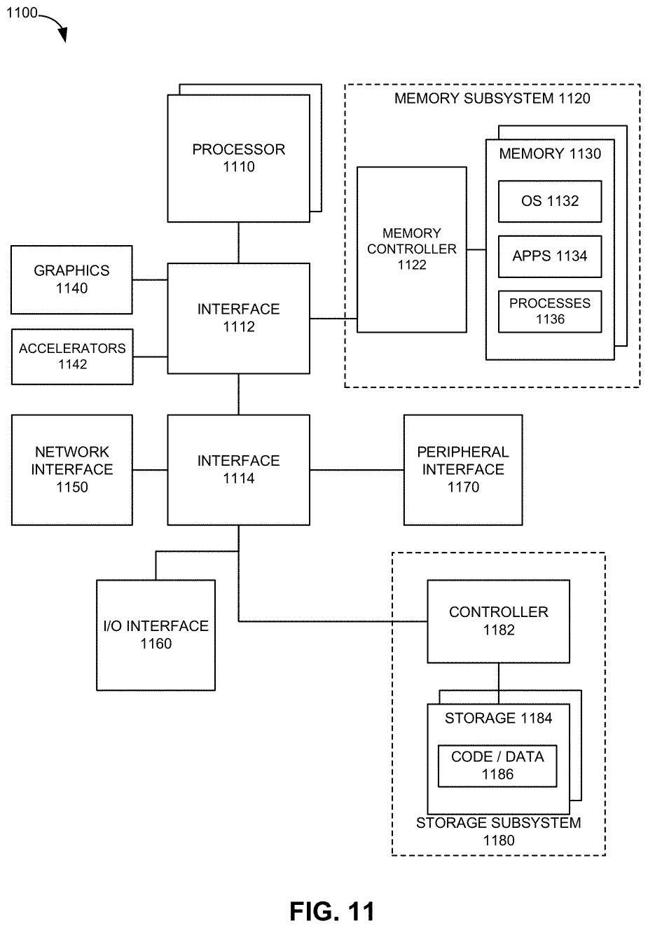

FIG. 11 depicts an example computing system. Components of system 1100 (e.g., processor 1110, accelerators 1142, memory subsystem 1120, and so forth) can be utilized to perform data compression with dictionary matching and post processing, as described herein. System 1100 includes processor 1110, which provides processing, operation management, and execution of instructions for system 1100. Processor 1110 can include any type of microprocessor, central processing unit (CPU), graphics processing unit (GPU), processing core, or other processing hardware to provide processing for system 1100, or a combination of processors. Processor 1110 controls the overall operation of system 1100, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, system 1100 includes interface 1112 coupled to processor 1110, which can represent a higher speed interface or a high throughput interface for system components that needs higher bandwidth connections, such as memory subsystem 1120 or graphics interface components 1140, or accelerators 1142. Interface 1112 represents an interface circuit, which can be a standalone component or integrated onto a processor die. Where present, graphics interface 1140 interfaces to graphics components for providing a visual display to a user of system 1100. In one example, graphics interface 1140 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 1140 generates a display based on data stored in memory 1130 or based on operations executed by processor 1110 or both. In one example, graphics interface 1140 generates a display based on data stored in memory 1130 or based on operations executed by processor 1110 or both.

Accelerators 1142 can be a fixed function or programmable offload engine that can be accessed or used by a processor 1110. For example, an accelerator among accelerators 1142 can provide compression (DC) capability, cryptography services such as public key encryption (PKE), cipher, hash/authentication capabilities, decryption, or other capabilities or services. In some embodiments, in addition or alternatively, an accelerator among accelerators 1142 provides field select controller capabilities as described herein. In some cases, accelerators 1142 can be integrated into a CPU socket (e.g., a connector to a motherboard or circuit board that includes a CPU and provides an electrical interface with the CPU). For example, accelerators 1142 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 1142 can provide multiple neural networks, CPUs, processor cores, general purpose graphics processing units, or graphics processing units can be made available for use by artificial intelligence (AI) or machine learning (ML) models. For example, the AI model can use or include one or more of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 1120 represents the main memory of system 1100 and provides storage for code to be executed by processor 1110, or data values to be used in executing a routine. Memory subsystem 1120 can include one or more memory devices 1130 such as read-only memory (ROM), flash memory, one or more varieties of random access memory (RAM) such as DRAM, or other memory devices, or a combination of such devices. Memory 1130 stores and hosts, among other things, operating system (OS) 1132 to provide a software platform for execution of instructions in system 1100. Additionally, applications 1134 can execute on the software platform of OS 1132 from memory 1130. Applications 1134 represent programs that have their own operational logic to perform execution of one or more functions. Processes 1136 represent agents or routines that provide auxiliary functions to OS 1132 or one or more applications 1134 or a combination. OS 1132, applications 1134, and processes 1136 provide software logic to provide functions for system 1100. In one example, memory subsystem 1120 includes memory controller 1122, which is a memory controller to generate and issue commands to memory 1130. It will be understood that memory controller 1122 could be a physical part of processor 1110 or a physical part of interface 1112. For example, memory controller 1122 can be an integrated memory controller, integrated onto a circuit with processor 1110.

While not specifically illustrated, it will be understood that system 1100 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a Hyper Transport or industry standard architecture (ISA) bus, a small computer system interface (SCSI) bus, a universal serial bus (USB), or an Institute of Electrical and Electronics Engineers (IEEE) standard 1394 bus (Firewire).

In one example, system 1100 includes interface 1114, which can be coupled to interface 1112. In one example, interface 1114 represents an interface circuit, which can include standalone components and integrated circuitry. In one example, multiple user interface components or peripheral components, or both, couple to interface 1114. Network interface 1150 provides system 1100 the ability to communicate with remote devices (e.g., servers or other computing devices) over one or more networks. Network interface 1150 can include an Ethernet adapter, wireless interconnection components, cellular network interconnection components, USB (universal serial bus), or other wired or wireless standards-based or proprietary interfaces. Network interface 1150 can transmit data to a device that is in the same data center or rack or a remote device, which can include sending data stored in memory.

Network interface 1150 can include one or more of: a network interface controller (NIC), a remote direct memory access (RDMA)-enabled NIC, SmartNIC, router, switch, or network-attached appliance. Some examples of network interface 1150 are part of an Infrastructure Processing Unit (IPU) or data processing unit (DPU) or utilized by an IPU or DPU. An xPU can refer at least to an IPU, DPU, GPU, GPGPU, or other processing units (e.g., accelerator devices). An IPU or DPU can include a network interface with one or more programmable pipelines or fixed function processors to perform offload of operations that could have been performed by a CPU. Programmable pipeline can be configured or programmed using languages based on one or more of: P4, Software for Open Networking in the Cloud (SONiC), C, Python, Broadcom Network Programming Language (NPL), Nvidia® CUDA®, Nvidia® DOCA™, Infrastructure Programmer Development Kit (IPDK), or x86 compatible executable binaries or other executable binaries.

In one example, system 1100 includes one or more input/output (I/O) interface(s) 1160. I/O interface 1160 can include one or more interface components through which a user interacts with system 1100 (e.g., audio, alphanumeric, tactile/touch, or other interfacing). Peripheral interface 1170 can include any hardware interface not specifically mentioned above. Peripherals refer generally to devices that connect dependently to system 1100. A dependent connection is one where system 1100 provides the software platform or hardware platform or both on which operation executes, and with which a user interacts.

In one example, system 1100 includes storage subsystem 1180 to store data in a nonvolatile manner. In one example, in certain system implementations, at least certain components of storage 1180 can overlap with components of memory subsystem 1120. Storage subsystem 1180 includes storage device(s) 1184, which can be or include any conventional medium for storing large amounts of data in a nonvolatile manner, such as one or more magnetic, solid state, or optical based disks, or a combination. Storage 1184 holds code or instructions and data 1186 in a persistent state (e.g., the value is retained despite interruption of power to system 1100). Storage 1184 can be generically considered to be a “memory,” although memory 1130 is typically the executing or operating memory to provide instructions to processor 1110. Whereas storage 1184 is nonvolatile, memory 1130 can include volatile memory (e.g., the value or state of the data is indeterminate if power is interrupted to system 1100). In one example, storage subsystem 1180 includes controller 1182 to interface with storage 1184. In one example controller 1182 is a physical part of interface 1114 or processor 1110 or can include circuits or logic in both processor 1110 and interface 1114.

A volatile memory is memory whose state (and therefore the data stored in it) is indeterminate if power is interrupted to the device. Dynamic volatile memory uses refreshing the data stored in the device to maintain state. One example of dynamic volatile memory incudes DRAM (Dynamic Random Access Memory), or some variant such as Synchronous DRAM (SDRAM). An example of a volatile memory include a cache. A memory subsystem as described herein may be compatible with a number of memory technologies, such as those consistent with specifications from JEDEC (Joint Electronic Device Engineering Council) or others or combinations of memory technologies, and technologies based on derivatives or extensions of such specifications.

A non-volatile memory (NVM) device is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), Intel® Optane™ memory, NVM devices that use chalcogenide phase change material (for example, chalcogenide glass), a combination of one or more of the above, or other memory.

A power source (not depicted) provides power to the components of system 1100. More specifically, power source typically interfaces to one or multiple power supplies in system 1100 to provide power to the components of system 1100. In one example, the power supply includes an AC to DC (alternating current to direct current) adapter to plug into a wall outlet. Such AC power can be renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, system 1100 can be implemented using interconnected compute sleds of processors, memories, storages, network interfaces, and other components. High speed interconnects can be used such as: Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (RoCE), Peripheral Component Interconnect express (PCIe), Intel QuickPath Interconnect (QPI), Intel® Ultra Path Interconnect (UPI), Intel On-Chip System Fabric (IOSF), Omni-Path, Compute Express Link (CXL), Universal Chiplet Interconnect Express (UCIe), HyperTransport, high-speed fabric, NVLink, Advanced Microcontroller Bus Architecture (AMBA) interconnect, OpenCAPI, Gen-Z, Infinity Fabric (IF), Cache Coherent Interconnect for Accelerators (CCIX), 3GPP Long Term Evolution (LTE) (4G), 3GPP 5G, and variations thereof. Data can be copied or stored to virtualized storage nodes or accessed using a protocol such as NVMe over Fabrics (NVMe-oF) or NVMe.

Communications between devices can take place using a network that provides chip-to-chip communications, die-to-die communications, packet-based communications, communications over a device interface, fabric-based communications, and so forth. A die-to-die communications can be consistent with Embedded Multi-Die Interconnect Bridge (EMIB).

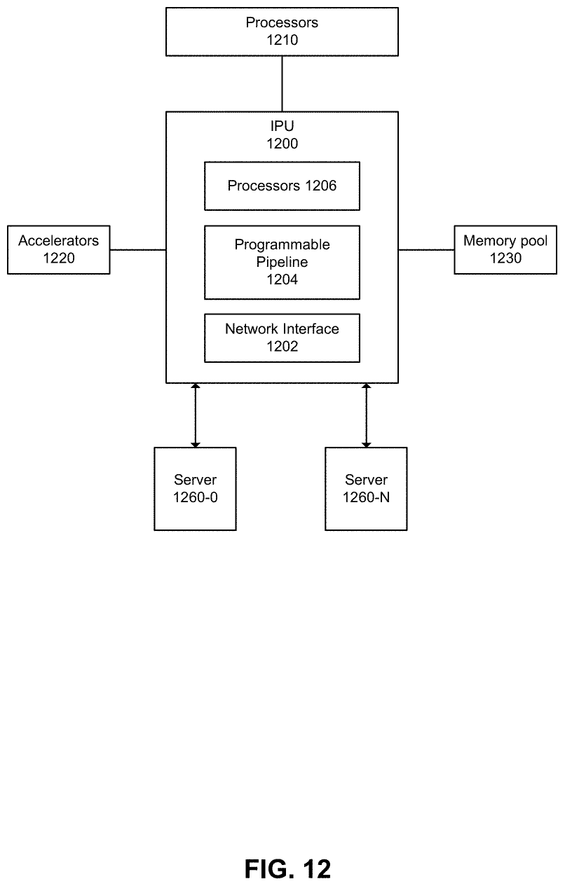

FIG. 12 depicts an example system. In this system, IPU 1200 manages performance of one or more processes using one or more of processors 1206, processors 1210, accelerators 1220, memory pool 1230, or servers 1240-0 to 1240-N, where N is an integer of 1 or more. In some examples, processors 1206 of IPU 1200 can execute one or more processes, applications, VMs, containers, microservices, and so forth that request performance of workloads by one or more of: processors 1210, accelerators 1220, memory pool 1230, and/or servers 1240-0 to 1240-N. IPU 1200 can utilize network interface 1202 or one or more device interfaces to communicate with processors 1210, accelerators 1220, memory pool 1230, and/or servers 1240-0 to 1240-N. IPU 1200 can utilize programmable pipeline 1204 to process packets that are to be transmitted from network interface 1202 or packets received from network interface 1202. Programmable pipeline 1204 and/or processors 1206 can be configured to perform data compression (e.g., dictionary matching and post processing) at least for data received in at least one packet or to be transmitted in at least one packet, as described herein.

Embodiments herein may be implemented in various types of computing, smart phones, tablets, personal computers, and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (ICs) and other components mounted to the board.

In some examples, network interface and other embodiments described herein can be used in connection with a base station (e.g., 3G, 4G, 5G and so forth), macro base station (e.g., 5G networks), picostation (e.g., an IEEE 802.11 compatible access point), nanostation (e.g., for Point-to-MultiPoint (PtMP) applications), micro data center, on-premise data centers, off-premise data centers, edge network elements, fog network elements, and/or hybrid data centers (e.g., data center that use virtualization, content delivery network (CDN), cloud and software-defined networking to deliver application workloads across physical data centers and distributed multi-cloud environments). Systems and components described herein can be made available for use by a cloud service provider (CSP), or communication service provider (CoSP).

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation. A processor can be one or more combination of a hardware state machine, digital control logic, central processing unit, or any hardware, firmware and/or software elements.

Some examples may be implemented using or as an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner, or syntax, for instructing a machine, computing device or system to perform a certain function. The instructions may be implemented using any suitable high-level, low-level, object-oriented, visual, compiled and/or interpreted programming language.

One or more aspects of at least one example may be implemented by representative instructions stored on at least one machine-readable medium which represents various logic within the processor, which when read by a machine, computing device or system causes the machine, computing device or system to fabricate logic to perform the techniques described herein. Such representations, known as “IP cores” may be stored on a tangible, machine readable medium and supplied to various customers or manufacturing facilities to load into the fabrication machines that actually make the logic or processor.

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission, or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal. The terms “follow” or “after” can refer to immediately following or following after some other event or events. Other sequences of operations may also be performed according to alternative embodiments. Furthermore, additional operations may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

Illustrative examples of the devices, systems, and methods disclosed herein are provided below. An embodiment of the devices, systems, and methods may include any one or more, and any combination of, the examples described below.

Example 1 includes one or more examples and includes an apparatus comprising: circuitry to perform data compression by performing dictionary matching of data using hardware circuitry to generate dictionary matched results and post-processing of dictionary matched results using software executed by a processor.

Example 2 includes one or more examples, wherein the dictionary matching comprises LZ77 dictionary matching.

Example 3 includes one or more examples, wherein the dictionary matching occurs on multiple segments of data in parallel.

Example 4 includes one or more examples, wherein the post-processing comprises conversion of LZ77 based on LZ4s into a sequence.

Example 5 includes one or more examples, wherein the post-processing comprises Zstandard entropy encoding.

Example 6 includes one or more examples, wherein the data compression comprises a lossless data compression.

Example 7 includes one or more examples, wherein the data compression is consistent with one or more of: Zstandard, Google® Broth, DEFLATE, LZ4, or LZ77.

Example 8 includes one or more examples, and includes at least one central processing unit to execute an application that is to issue a request to perform data compression to the circuitry.

Example 9 includes one or more examples, and includes a server comprising the at least one central processing unit and the circuitry.

Example 10 includes one or more examples, and includes a computer-readable medium comprising instructions stored thereon, that if executed, cause one or more processors to: request to perform data compression by performing dictionary matching of data using hardware circuitry to generate dictionary matched results and post-processing of dictionary matched results using software executed by a processor.

Example 11 includes one or more examples, wherein the dictionary matching comprises LZ77 dictionary matching.

Example 12 includes one or more examples, wherein the dictionary matching occurs on multiple segments of data in parallel.

Example 13 includes one or more examples, wherein the post-processing comprises conversion of LZ77 based on LZ4s into a sequence.

Example 14 includes one or more examples, wherein the post-processing comprises Zstandard entropy encoding.

Example 15 includes one or more examples, wherein the data compression comprises a lossless data compression.

Example 16 includes one or more examples, wherein the data compression is consistent with one or more of: Zstandard, Google® Broth, DEFLATE, LZ4, or LZ77.

Example 17 includes one or more examples, and includes a method comprising: performing data compression by performing dictionary matching of data using hardware circuitry to generate dictionary matched results and post-processing of dictionary matched results using software executed by a processor.

Example 18 includes one or more examples, wherein the dictionary matching comprises LZ77 dictionary matching.

Example 19 includes one or more examples, wherein the dictionary matching occurs on multiple segments of data in parallel.

Example 20 includes one or more examples, wherein the post-processing comprises conversion of LZ77 based on LZ4s into a sequence.

What is claimed is:

1. An apparatus comprising:
circuitry to perform data compression by performing dictionary matching of data using hardware circuitry to generate dictionary matched results and post-processing of dictionary matched results using software executed by a processor.

2. The apparatus of claim 1, wherein the dictionary matching comprises LZ77 dictionary matching.

3. The apparatus of claim 1, wherein the dictionary matching occurs on multiple segments of data in parallel.

4. The apparatus of claim 1, wherein the post-processing comprises conversion of LZ77 based on LZ4s into a sequence.

5. The apparatus of claim 1, wherein the post-processing comprises Zstandard entropy encoding.

6. The apparatus of claim 1, wherein the data compression comprises a lossless data compression.

7. The apparatus of claim 1, wherein the data compression is consistent with one or more of: Zstandard, Google® Broth, DEFLATE, LZ4, or LZ77.

8. The apparatus of claim 1, comprising:
at least one central processing unit to execute an application that is to issue a request to perform data compression to the circuitry.

9. The apparatus of claim 8, comprising:
a server comprising the at least one central processing unit and the circuitry.

10. A computer-readable medium comprising instructions stored thereon, that if executed, cause one or more processors to:
request to perform data compression by performing dictionary matching of data using hardware circuitry to generate dictionary matched results and post-processing of dictionary matched results using software executed by a processor.

11. The computer-readable medium of claim 10, wherein the dictionary matching comprises LZ77 dictionary matching.

12. The computer-readable medium of claim 10, wherein the dictionary matching occurs on multiple segments of data in parallel.

13. The computer-readable medium of claim 10, wherein the post-processing comprises conversion of LZ77 based on LZ4s into a sequence.

14. The computer-readable medium of claim 10, wherein the post-processing comprises Zstandard entropy encoding.

15. The computer-readable medium of claim 10, wherein the data compression comprises a lossless data compression.

16. The computer-readable medium of claim 10, wherein the data compression is consistent with one or more of: Zstandard, Google® Broth, DEFLATE, LZ4, or LZ77.

17. A method comprising:
performing data compression by performing dictionary matching of data using hardware circuitry to generate dictionary matched results and post-processing of dictionary matched results using software executed by a processor.

18. The method of claim 17, wherein the dictionary matching comprises LZ77 dictionary matching.

19. The method of claim 17, wherein the dictionary matching occurs on multiple segments of data in parallel.

20. The method of claim 17, wherein the post-processing comprises conversion of LZ77 based on LZ4s into a sequence.
